(19) United States
(12) Patent Application Publication
(10) Pub. No.: US 2022/0216670 A1
(43) Pub. Date: Jul. 7, 2022

(54) OPTICAL MODULE AND TEMPERATURE CONTROL METHOD THEREOF

(71) Applicant: Hisense Broadband Multimedia Technologies Co., Ltd., Qingdao (CN)

(72) Inventors: Tao WU, Qingdao (CN); Shuang JIN, Qingdao (CN); Jianwei MU, Qingdao (CN); Hongtu PU, Qingdao (CN)

(73) Assignee: Hisense Broadband Multimedia Technologies Co., Ltd., Qingdao (CN)

(21) Appl. No.: 17/704,373

(22) Filed: Mar. 25, 2022

Related U.S. Application Data
(63) Continuation of application No. PCT/CN2021/101605, filed on Jun. 22, 2021.

(30) Foreign Application Priority Data
Oct. 22, 2020 (CN) 202011141727.3
Oct. 27, 2020 (CN) 202011164206.X

(51) Int. Cl. H01S 5/024; H01S 5/026; H01S 5/0237

(52) U.S. Cl. CPC H01S 5/02415; H01S 5/0237; H01S 5/0261

(57) ABSTRACT

An optical module includes a shell, a circuit board, a light-emitting device, a sensor assembly and a processor. The circuit board is disposed in the shell. The light-emitting device is disposed in the shell, and includes a non-hermetically sealed cover, a laser chip and a thermo electric cooler. The thermo electric cooler is disposed in the cover and is configured to adjust a temperature of the heat exchange surface of the thermo electric cooler connected to the laser chip. The sensor assembly is disposed on the circuit board and is configured to detect ambient data inside the optical module, the ambient data including at least ambient humidity. The processor is disposed on the circuit board, and is configured to receive the ambient data detected by and sent from the sensor assembly, and control the thermo electric cooler to adjust the temperature of the heat exchange surface of the thermo electric cooler to a target temperature according to the ambient data.

### CROSS-REFERENCE TO RELATED APPLICATIONS

This application is a continuation application of International Application No. PCT/CN2021/101605 filed on Jun. 22, 2021, which claims priority to Chinese Patent Application No. 202011141727.3 filed on Oct. 22, 2020, Chinese Patent Application No. 202011164206.X filed on Oct. 27, 2020. The entirety of each is incorporated herein by reference.

### TECHNICAL FIELD

The present disclosure relates to the field of optical communication technologies, and in particular, to an optical module and a temperature control method thereof.

### BACKGROUND

In the development process of high-speed optical communication products, with the improvement of signal transmission rate, people are having higher requirements for cost reduction. In traditional optical communication products, the light-emitting device usually adopts a hermetically sealed cover to encapsulate various optoelectronic devices, so as to prevent moisture from entering the inside of the cover and ensure that the entire light-emitting device can operate normally in high temperature and high humidity environments. However, the hermetically sealed cover is very expensive and cannot meet people's increasingly higher requirements for cost reduction. Therefore, the non-hermetic sealing method has become the main development direction to replace the hermetic sealing method due to its lower cost and more flexible design.

### SUMMARY

In one aspect, an optical module is provided. The optical module includes a shell, a circuit board, a light-emitting device, a sensor assembly, and a processor. The circuit board is disposed in the shell. The light-emitting device is disposed in the shell, and includes a non-hermetically sealed cover, a laser chip and a thermo electric cooler. The laser chip is disposed in the cover and on the thermo electric cooler, and is configured to emit an optical signal. The thermo electric cooler is disposed in the cover, and is configured to adjust a temperature of the heat exchange surface of the thermo electric cooler connected to the laser chip. The sensor assembly is disposed on the circuit board, and is configured to detect ambient data inside the optical module, the ambient data including at least ambient humidity. The processor is disposed on the circuit board, and is configured to receive the ambient data detected by and sent from the sensor assembly, and control the thermo electric cooler to adjust the temperature of the heat exchange surface of the thermo electric cooler to a target temperature according to the ambient data.

In another aspect, a temperature control method of an optical module is provided. The method includes: obtaining, by a sensor assembly, ambient data inside the optical module, and sending, by the sensor assembly, the obtained ambient data to a processor, the ambient data including at least ambient humidity; and receiving, by the processor, the ambient data obtained by the sensor assembly, and controlling, by the processor, the thermo electric cooler to adjust a temperature of a heat exchange surface of a thermo electric cooler to a target temperature according to the ambient data.

In yet another aspect, a non-transitory computer-readable storage medium is provided. The non-transitory computer-readable storage medium has stored thereon computer program instructions that, when run on a processor, cause the processor to execute the above temperature control method of the optical module.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, and are not limitations on an actual size of a product, an actual process of a method and an actual timing of a signal involved in the embodiments of the present disclosure.

FIG. 1 is a connection diagram of an optical communication system, in accordance with some embodiments;

FIG. 2 is a structural diagram of an optical network terminal, in accordance with some embodiments;

FIG. 3 is a structural diagram of an optical module, in accordance with some embodiments;

FIG. 4 is an exploded structural diagram of an optical module, in accordance with some embodiments;

FIG. 5A is a structural diagram of an optical module with an upper shell, a lower shell, and an unlocking component removed, in accordance with some embodiments;

FIG. 5B is a diagram of an internal structure of a light-emitting device, in accordance with some embodiments;

FIG. 6 is a structural diagram of a sensor assembly, in accordance with some embodiments;

FIG. 7 is a diagram showing an electrical connection between a sensor assembly and a microcontroller unit (MCU), in accordance with some embodiments;

FIG. 8 is a diagram showing a relationship between ambient humidity and dew-point temperature of an optical module under different ambient temperatures, in accordance with some embodiments;

FIG. 9 is a flow diagram of a temperature control method of an optical module, in accordance with some embodiments; and

FIG. 10 is a flow diagram of another temperature control method of an optical module, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, “a plurality of/the plurality of” means two or more unless otherwise specified.

In the description of some embodiments, the terms “coupled”, “connected” and derivatives thereof may be used. For example, the term “connected” may be used when describing some embodiments to indicate that two or more components are in direct physical or electrical contact with each other. For another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “At least one of A, B, and C” has the same meaning as the phrase “at least one of A, B, or C”, and both include the following combinations of A, B, and C: only A, only B, only C, a combination of A and B, a combination of A and C, a combination of B and C, and a combination of A, B and C.

The phrase “A and/or B” includes the following three combinations: only A, only B, and a combination of A and B.

As used herein, depending on the context, the term “if” is optionally construed as “when” or “in a case where” or “in response to determining” or “in response to detecting”. Similarly, depending on the context, the phrase “if it is determined . . . ” or “if [the stated condition or event] is detected” is optionally construed as “when determining . . . ” or “in response to determining . . . ” or “in a case where [the stated condition or event] is detected” or “in response to detecting [the stated condition or event]”.

The phrase “applicable to” or “configured to” as used herein indicates an open and inclusive expression, which does not exclude devices that are applicable to or configured to perform additional tasks or steps.

In addition, the phrase “based on” as used herein indicates openness and inclusiveness, since processes, steps, calculations or other actions “based on” one or more of the stated conditions or values may be based on additional conditions or exceed the stated values in practice.

As used herein, the term “about”, “substantially” or “approximately” includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of a measurement system).

In optical communication technology, an optical signal is used to carry information to be transmitted, and the optical signal carrying the information is transmitted to an information processing device such as a computer through an information transmission device such as an optical fiber or an optical waveguide, so as to achieve information transmission. Due to the passive transmission characteristic of the optical signal when being transmitted through the optical fiber or the optical waveguide, low-cost and low-loss information transmission may be achieved. In addition, since a signal transmitted by the information transmission device such as the optical fiber or the optical waveguide is the an optical signal, and a signal that may be recognized and processed by the information processing device such as a computer is an electrical signal, in order to establish information connection between the information transmission device such as the optical fiber or the optical waveguide and the information processing device such as the computer, there is a need to achieve interconversion between the electrical signal and the optical signal. Common information processing devices include a router, a switch, and an electronic computer.

In the field of optical fiber communication technology, an optical module may achieve interconversion between the optical signal and the electrical signal. The optical module includes an optical port and an electrical port. The optical module achieves optical communication with the information transmission device such as the optical fiber or the optical waveguide through the optical port, and the optical module achieves electrical connection with an optical network terminal (e.g., an optical modem) through the electrical port. The electrical connection is mainly to implement power supply, Inter-Integrated circuit (I2C) signal transmission, data signal transmission, and grounding functions. The optical network terminal transmits the electrical signal to the information processing device such as a computer through a network cable or wireless fidelity (\Ni-Fi).

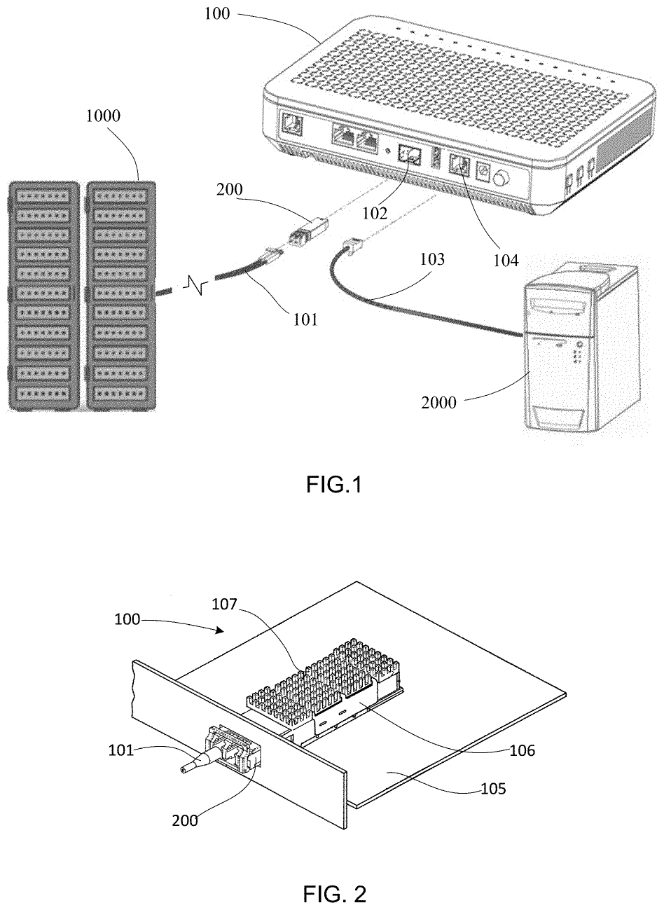

FIG. 1 is a connection diagram of an optical communication system, in accordance with some embodiments. As shown in FIG. 1, the optical communication system includes a remote server 1000, a local information processing device 2000, an optical network terminal 100, an optical module 200, an optical fiber 101 and a network cable 103.

An end of the optical fiber 101 is connected to the remote server 1000, and another end thereof is connected to the optical network terminal 100 through the optical module 200. The optical fiber itself supports long-distance signal transmission, for example, signal transmission over several kilometers (6 kilometers to 8 kilometers). On this basis, if repeaters are used, theoretically, it may be possible to achieve infinite-distance transmission. Therefore, in a typical optical communication system, a distance between the remote server 1000 and the optical network terminal 100 may typically reach several kilometers, dozens of kilometers, or hundreds of kilometers.

An end of the network cable 103 is connected to the local information processing device 2000, and another end thereof is connected to the optical network terminal 100. The local information processing device 2000 includes one or more of a router, a switch, a computer, a mobile phone, a tablet computer or a television.

A physical distance between the remote server 1000 and the optical network terminal 100 is greater than a physical distance between the local information processing device 2000 and the optical network terminal 100. Connection between the local information processing device 2000 and the remote server 1000 is achieved by the optical fiber 101 and the network cable 103, and connection between the optical fiber 101 and the network cable 103 is achieved by the optical module 200 and the optical network terminal 100.

The optical network terminal 100 includes a housing in a substantially cuboid shape, and an optical module interface 102 and a network cable interface 104 that are disposed on the housing. The optical module interface 102 is configured for connecting the optical module 200, so that a bidirectional electrical signal connection is established between the optical network terminal 100 and the optical module 200. The network cable interface 104 is configured for connecting the network cable 103, so that a bidirectional electrical signal connection is established between the optical network terminal 100 and the network cable 103. Connection between the optical module 200 and the network cable 103 is established through the optical network terminal 100. For example, the optical network terminal 100 transmits an electrical signal from the optical module 200 to the network cable 103, and transmits an electrical signal from the network cable 103 to the optical module 200. Therefore, the optical network terminal 100, as a master monitor of the optical module 200, may monitor operation of the optical module 200. In addition to the optical network terminal 100, the master monitors of the optical module 200 may further include an optical line terminal (OLT).

The optical module 200 includes an electrical port and an optical port. The optical port is configured for connecting the optical fiber 101, so that a bidirectional optical signal connection between the optical module 200 and the optical fiber 101 is established; and the electrical port is configured for connecting the optical network terminal 100, so that a bidirectional electrical signal connection is established between the optical module 200 and the optical network terminal 100. The optical module 200 may achieve interconversion between the optical signal and the electrical signal, so that a connection is established between the optical fiber 101 and the optical network terminal 100. For example, an optical signal from the optical fiber 101 is converted into an electrical signal by the optical module 200, and then the electrical signal is input into the optical network terminal 100; an electrical signal from the optical network terminal 100 is converted into an optical signal by the optical module 200, and then the optical signal is input into the optical fiber 101. Since the optical module 200 is a tool for achieving interconversion between the optical signal and the electrical signal, and doesn't have a data processing function, the information does not change in the above photoelectric conversion process.

A bidirectional signal transmission channel has been established between the remote server 1000 and the local information processing device 200 through the optical fiber 101, the optical module 200, the optical network terminal 100 and the network cable 103.

FIG. 2 is a structural diagram of an optical network terminal, in accordance with some embodiments. In order to clearly show a connection relationship between the optical module 200 and the optical network terminal 100, FIG. 2 only shows a structure of the optical network terminal 100 that is related to the optical module 200. As shown in FIG. 2, the optical network terminal 100 further includes a circuit board 105 disposed in the housing, a cage 106 disposed on a surface of the circuit board, a heat sink 107 disposed on the cage 106, and an electrical connector disposed inside the cage 106. The electrical connector is configured for connecting the electrical port of the optical module 200. The heat sink 107 has protruding portions such as fins for increasing a heat dissipation area.

The optical module 200 is inserted into the cage 106 of the optical network terminal 100, and is fixed by the cage 106. Heat generated by the optical module 200 is conducted to the cage 106 and is then dissipated through the heat sink 107. After the optical module 200 is inserted into the cage 106, the electrical port of the optical module 200 is connected to the electrical connector in the cage 106, so that a bidirectional electrical signal connection is established between the optical module 200 and the optical network terminal 100. In addition, the optical port of the optical module 200 is connected to the optical fiber 101, so that a bidirectional optical signal connection is established between the optical module 200 and the optical fiber 101.

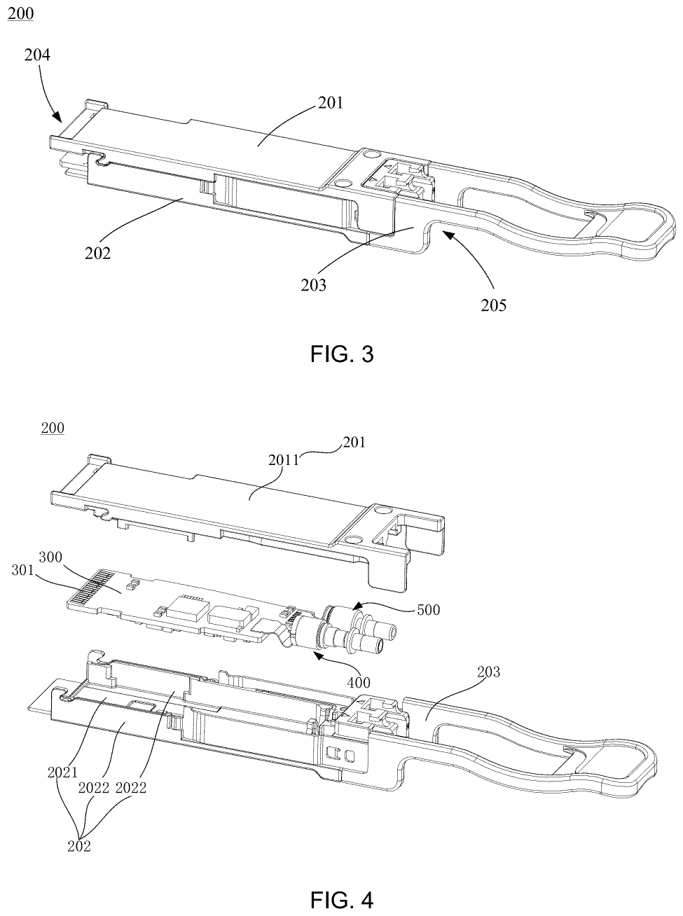

FIG. 3 is a structural diagram of an optical module, in accordance with some embodiments, and FIG. 4 is an exploded structural diagram of an optical module, in accordance with some embodiments. As shown in FIGS. 3 and 4, the optical module 200 includes a shell, a circuit board 300 disposed inside the shell, a light-emitting device 400 and a light-receiving device 500.

The shell includes an upper shell 201 and a lower shell 202. The upper shell 201 covers the lower shell 202 to form the shell having two openings; and an outer contour of the shell is generally in a cuboid shape.

In some embodiments, the lower shell 202 includes a bottom plate 2021 and two lower side plates 2022 that are located on two sides of the bottom plate 2021 and disposed perpendicular to the bottom plate 2021; the upper shell 201 includes a cover plate 2011, and the cover plate 2011 covers the two lower side plates 2022 of the lower shell 202 to form the shell.

In some embodiments, the lower shell 202 includes a bottom plate 2021 and two lower side plates 2022 that are located on two sides of the bottom plate 2021 and disposed perpendicular to the bottom plate 2021; the upper shell 201 includes a cover plate 2011 and two upper side plates that are located on two sides of the cover plate 2011 and disposed perpendicular to the cover plate 2011. The two upper side plates are combined with the two lower side plates 2022 respectively, so that the upper shell 201 covers the lower shell 202.

A direction in which a connection line between the two openings 204 and 205 extends may be the same as a longitudinal direction of the optical module 200, or may not be the same as the longitudinal direction of the optical module 200. For example, the opening 204 is located at an end (a left end in FIG. 3) of the optical module 200, and the opening 205 is also located at an end (a right end in FIG. 3) of the optical module 200. Alternatively, the opening 204 is located at an end of the optical module 200, and the opening 205 is located at a side of the optical module 200. The opening 204 is the electrical port, and a connecting finger 301 of the circuit board 300 extends out from the electrical port 204, and is inserted into the master monitor (e.g., the optical network terminal 100). The opening 205 is the optical port, and is configured for connecting the external optical fiber 101, so that the optical fiber 101 is connected to the light-emitting device 400 and the light-receiving device 500 in the optical module 200.

By adopting an assembly mode of combining the upper shell 201 and the lower shell 202, it may be easier to install the circuit board 300, the light-emitting device 400, the light-receiving device 500 and other optical devices into the shell, and the upper shell 201 and the lower shell 202 may provide sealing and protection for these devices. In addition, when the circuit board 300, the light-emitting device 400, the light-receiving device 500 and other devices are assembled, it may be easier to arrange the positioning elements, heat dissipation elements, and electromagnetic shielding elements of these devices, which facilitates automated production.

In some embodiments, the upper shell 201 and the lower shell 202 are made of a metallic material, which helps achieve electromagnetic shielding and heat dissipation.

In some embodiments, the optical module 200 further includes an unlocking component 203 located outside the shell. The unlocking component 203 is configured to implement a fixed connection between the optical module 200 and the master monitor, or to release the fixed connection between the optical module 200 and the master monitor.

For example, the unlocking component 203 is located outside the two lower side plates 2022 of the lower shell 202, and has an engagement element that is matched with the cage 106 of the master monitor. When the optical module 200 is inserted into the cage 106, the optical module 200 is fixed in the cage 106 through the engagement element of the unlocking component 203. When the unlocking component 203 is pulled, the engagement element of the unlocking component 203 moves along with the unlocking component 203, and then a connection relationship between the engagement element and the master monitor is changed to release the engagement between the optical module 200 and the master monitor, so that the optical module 200 may be pulled out of the cage 106.

The circuit board 300 includes circuit traces, electronic elements, chips, etc. Through the circuit traces, the electronic elements and the chips are connected together according to circuit design, so as to implement power supply, electrical signal transmission, and grounding functions. The electronic elements may include, for example, a capacitor, a resistor, a triode, and a metal-oxide-semiconductor field-effect transistor (MOSFET). The chips may include, for example, a microcontroller unit (MCU), a laser driving chip, a limiting amplifier, a clock and data recovery (CDR) chip, a power management chip or a digital signal processing (DSP) chip.

The circuit board 300 is generally a rigid circuit board. Since it is made of a relatively hard material, the rigid circuit board may also have a support function. For example, the rigid circuit board may stably support the electronic elements and the chips, and may also be inserted into the electrical connector in the cage 106 of the master monitor.

The circuit board 300 further includes a connecting finger 301 formed on an end surface thereof, and the connecting finger 301 is composed of a plurality of independent pins. The circuit board 300 is inserted into the cage 106, and is conductively connected to the electrical connector in the cage 106 through the connecting finger 301. The connecting finger 301 may be disposed on only one surface (e.g., an upper surface shown in FIG. 4) of the circuit board 300, or may be disposed on both the upper and lower surfaces of the circuit board 300 to adapt to an occasion where a large number of pins are needed. The connecting finger 301 is configured to establish an electrical connection with the master monitor to implement power supply, grounding, I2C signal transmission, and data signal transmission functions.

Of course, flexible circuit boards are also used in some optical modules. A flexible circuit board is generally used in conjunction with a rigid circuit board as a supplement for the rigid circuit board.

For a high-speed optical module, such as a 400G SR4 (maximum transmission distance: 500 meters) optical module, a 400G LR4 (maximum transmission distance: 10 kilometers) optical module, a 400G ER4 (maximum transmission distance: 40 kilometers) optical module, and other optical modules, as the signal transmission rate increases, people are having higher requirements for cost reduction. Traditional light-emitting device usually adopts a hermetically sealed cover to ensure the air tightness of the light-emitting device, so that the entire light-emitting device can operate normally in high temperature and high humidity environments.

The 400G SR4 optical module, 400G LR4 optical module and 400G ER4 optical module refer to optical modules that adopt 4 optical signal transmission channels with a transmission rate of 106 Gbit/s on the optical port side, and 8 electrical signal transmission channels with a transmission rate of 53 Gbit/s on the electrical port side, so as to realize a signal transmission rate of 400 Gbit/s. SR, LR and ER are used to classify the optical modules with a transmission rate of 400 Gbit/s according to the signal transmission distance. SR is short for “short range”, LR is short for “long range” and ER is short for “extended range”.

However, the hermetically sealed cover is very expensive and cannot meet people's increasingly stringent requirements for cost reduction. Therefore, the non-hermetic sealing method has become the main development direction to replace the hermetic sealing method due to its lower cost and more flexible design.

The light-emitting device 400 includes a non-hermetically sealed cover. For example, the flexible circuit board is inserted into the cover. An end of the flexible circuit board is electrically connected to a laser chip and other optical devices, and another end thereof is electrically connected to the circuit board 300. Since the cover has an opening that allows the flexible circuit board to pass through, the cover of the light-emitting device 400 becomes a cover that is not hermetically sealed. Or, the circuit board 300 is directly inserted into the cover, and the laser chip and other optical devices are disposed on the circuit board 300. Since the cover has an opening that allows the circuit board 300 to pass through, the cover of the light-emitting device 400 becomes a cover that is not hermetically sealed.

However, in the non-hermetically sealed structure of the light-emitting device 400, especially in a case where there is a thermo electric cooler (TEC), the laser chip and other optical devices are disposed on a heat exchange surface of the TEC. The TEC cools or heats the laser chip and other optical devices through the heat exchange surface, so as to decrease or increase the temperature of the laser chip and other optical devices, and ensure the normal operation of the laser chip and other optical devices. When the heat exchange surface of the TEC cools the laser chip and other optical devices, the heat exchange surface of the TEC usually has a low fixed temperature. In high temperature and high humidity environments, there is a slight air leakage in the cover due to the non-hermetically sealed structure of the light-emitting device 400. After a certain period of time, when the temperature of the heat exchange surface of the TEC drops below a dew point of the moisture inside the cover of the light-emitting device 400, the surfaces of key optical devices on the TEC will be covered with dew. As a result, the output power of the light-emitting device will decrease, and the light-emitting device may not even operate normally.

In order to solve the above problems, some embodiments of the present disclosure provide an optical module, which can monitor humidity data inside the optical module in real time, and adjust the cooling or heating temperature of the TEC correspondingly according to the humidity data. As a result, the key optical devices (e.g., a laser chip) in the light-emitting device 400 may operate at a temperature above the dew point inside the cover of the light-emitting device 400; therefore, it may be possible to prevent condensation on the surfaces of the key optical devices, and ensure that the entire optical module operates normally.

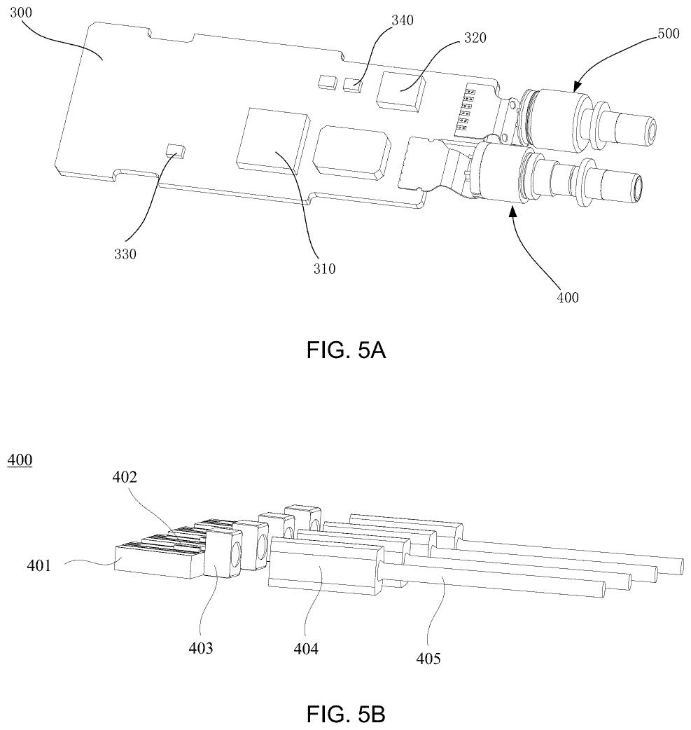

FIG. 5A is a structural diagram of an optical module with an upper shell 201, a lower shell 202, and an unlocking component 203 removed, in accordance with some embodiments. As shown in FIG. 5A, the optical module 200 further includes a microcontroller unit (MCU) 310, a power management chip 320, a sensor assembly 330, and a driving chip 340 of the TEC. The MCU 310, the power management chip 320 and the sensor assembly 330 are all disposed on the circuit board 300. The MCU 310 and the sensor assembly 330 are both electrically connected to the power management chip 320. The power management chip 320 is connected to the master monitor to adjust a voltage provided by the master monitor, so as to supply power to the MCU 310 and the sensor assembly 330.

The sensor assembly 330 is configured to detect ambient data inside the optical module 200. A communication signal interface of the sensor assembly 330 is connected to a communication signal interface of the MCU 310. The MCU 310 is configured to receive the ambient data detected by the sensor assembly 330, and control a cooling temperature or heating temperature of the TEC 401 (as shown in FIG. 5B) according to the ambient data, so that the cooling temperature or heating temperature of the TEC 401 may allow the key optical devices disposed on the TEC 401 to operate at an temperature above the dew point inside the cover, so as to prevent condensation on the surfaces of the key optical devices and ensure normal operation of the entire optical module.

FIG. 5B is a diagram of an internal structure of the light-emitting device 400, in accordance with some embodiments; and the cover of the light-emitting device 400 is omitted in FIG. 5B. As shown in FIG. 5B, the light-emitting device 400 includes a TEC 401, a laser chip 402, a focusing lens 403, an optical fiber adapter 404 and an internal optical fiber 405 that are located inside the cover.

The TEC 401 is disposed inside the cover, and is a main device for adjusting temperature in the optical module. A plurality of (four, to form four optical signal transmission channels) laser chips 402 are disposed on a surface of the TECs 401. The TECs 401 are configured to adjust a temperature of the heat exchange surfaces thereof connected to the laser chips 402; for example, the TECs 401 are configured to conduct the heat generated by the plurality of laser chips 402 to the cover, so that the heat is conducted to the outside of the optical module 200 through the cover; for another example, the TECs 401 are configured to maintain the temperature of the heat exchange surfaces thereof so as to avoid condensation. The plurality of laser chips 402 are configured to emit optical signals. A plurality of focusing lenses 403 are in one-to-one correspondence with the plurality of laser chips 402, and are configured to converge light emitted by corresponding laser chips 402, so that the light is subsequently coupled with the internal optical fibers 405 in the optical fiber adapters 404. The internal optical fibers 405 are connected to an external optical fiber that is connected to the optical port 205 of the optical module 200, so as to realize transmission of optical signals to the outside of the optical module 200.

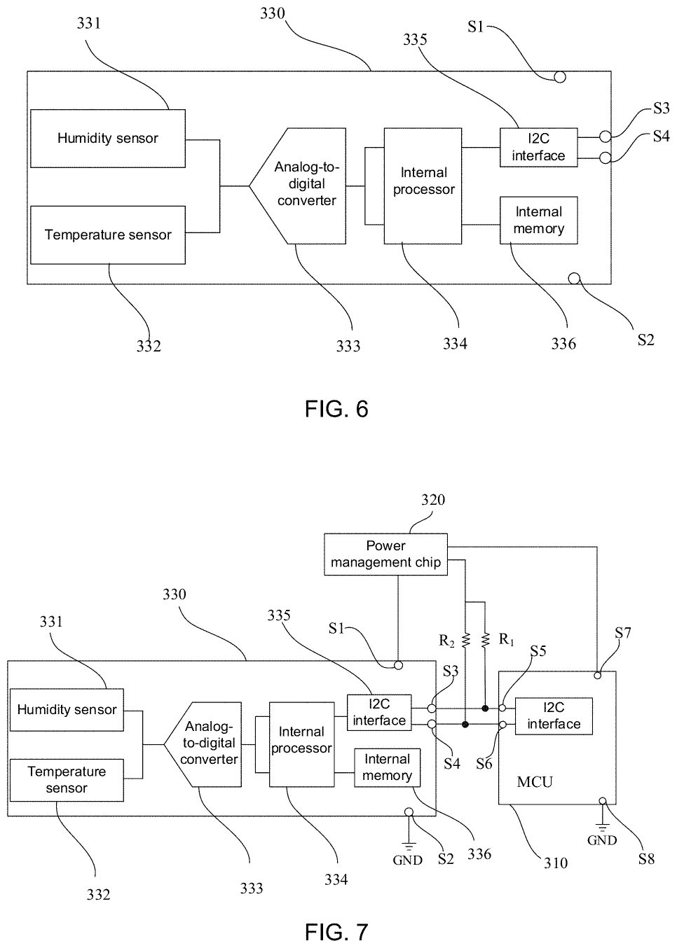

FIG. 6 is a structural diagram of a sensor assembly, in accordance with some embodiments. Referring to FIG. 6, in some embodiments, in a case where the sensor assembly 330 is configured to obtain the ambient humidity and ambient temperature inside the optical module 200 in real time, the sensor assembly 330 includes at least a humidity sensor 331 and a temperature sensor 332. The humidity sensor 331 is configured to obtain ambient humidity data inside the optical module 200 in real time; and the temperature sensor 332 is configured to obtain ambient temperature data inside the optical module 200 in real time. The ambient data detected by the sensor assembly 330 includes ambient humidity and ambient temperature inside the optical module 200. For example, the ambient humidity is relative humidity. The MCU 310 generates a control signal according to the obtained ambient humidity and ambient temperature, and transmits the control signal to the driving chip 340 of the TEC. The driving chip 340 of the TEC drivers the TEC 401 to decrease or increase the temperature of the heat exchange surface of the TEC, so as to adjust the temperature of the laser chip 402 and other optical devices on the heat exchange surface of the TEC, and avoid condensation on the laser chip and other optical devices.

In some embodiments, in a case where the sensor assembly 330 is configured to only detect the ambient humidity inside the optical module 200, the sensor assembly 330 includes at least a humidity sensor 331, but does not include a temperature sensor. The ambient data detected by the sensor assembly 330 includes the ambient humidity inside the optical module 200. In this case, the MCU 310 includes a temperature sensor, and the MCU 310 is able to detect the ambient temperature inside the optical module 200 in real time. The sensor assembly 330 transmits the detected ambient data to the MCU 310, and the MCU 310 generates a control signal according to the ambient temperature detected by itself and the obtained ambient humidity, and transmits the control signal to the driving chip 340 of the TEC. The driving chip 340 of the TEC drives the TEC to decrease or increase the temperature of the heat exchange surface of the TEC, so as to adjust the temperature of the laser chip and other optical devices on the heat exchange surface of the TEC, and avoid condensation on the laser chip and other optical devices.

In some embodiments, in a case where neither the sensor assembly 330 nor the MCU 310 includes a temperature sensor, the optical module 200 may include an additional temperature sensor. The MCU 310, the sensor assembly 330 and the additional temperature sensor are all disposed on the circuit board 300. The additional temperature sensor is electrically connected to the power management chip 320; and the power management chip 320 supplies power to the additional temperature sensor, so that the additional temperature sensor detects the temperature inside the optical module 200 in real time. The additional temperature sensor is further communicatively connected to the MCU 310, so as to transmit the detected ambient temperature data to the MCU 310.

In some embodiments, as shown in FIG. 6, in a case where the sensor assembly 330 includes the humidity sensor 331 and the temperature sensor 332, the humidity sensor 331 and the temperature sensor 332 transmit the ambient humidity and ambient temperature obtained in real time to the MCU 310 through an I2C interface 335 of the sensor assembly 330; the MCU 310 generates a control signal after processing the received ambient humidity and ambient temperature, and the control signal controls the cooling or heating temperature of the heat exchange surface of the TEC.

Since the cover of the light-emitting device 400 is a non-hermetically sealed cover, the air inside the optical module 200 is connected to the air inside the light emitting device 400. Therefore, the ambient humidity data and the ambient temperature data detected by the humidity sensor 331 and the temperature sensor 332 are the ambient humidity data and the ambient temperature data inside the light-emitting device 400.

In some embodiments, the driving chip 340 of the TEC is disposed on the circuit board 300, and the MCU 310 and the TEC 401 which is in the light-emitting device 400 are both electrically connected to the driving chip 340 of the TEC. The MCU 310 transmits the control signal to the driving chip 340 of the TEC, and the driving chip 340 of the TEC drives the TEC 401 to adjust the cooling or heating temperature according to the control signal, so as to adjust the operation temperature of the laser chip 402 on the TEC 401 and other optical devices.

In some embodiments, the driving chip of the TEC is integrated in the MCU 310, and the TEC 401 in the light-emitting device 400 is electrically connected to the driving chip of the TEC in the MCU 310.

It will be noted that, the optical module 200 is not limited to using the MCU 310 as a processor. In some embodiments, the processor includes a central processing unit (CPU), a microprocessor, an application specific integrated circuit (ASIC), and may be configured to execute corresponding operations described in the processor when the processor executes the program stored in the non-transitory computer readable medium coupled to the processor. The non-transitory computer-readable storage media may include a magnetic storage device (e.g., a hard disk, floppy disk or magnetic tape), a smart card, or a flash memory device (e.g., an erasable programmable read-only memory (EPROM)), card, stick, or keyboard driver).

FIG. 6 is a structural diagram of a sensor assembly 330, in accordance with some embodiments. As shown in FIG. 6, the sensor assembly 330 includes a humidity sensor 331, a temperature sensor 332, an analog-to-digital converter 333, an internal processor 334 and an I2C interface 335. An output end of the humidity sensor 331 and an output end of the temperature sensor 332 are both connected to an input end of the analog-to-digital converter 333; an output end of the analog-to-digital converter 333 is connected to an input end of the internal processor 334; an output end of the internal processor 334 is connected to an end of the I2C interface; the I2C interface is connected to a communication signal interface of the MCU 310 through an I2C line (e.g., a serial clock (SCL) line, or a serial data (SDA) line).

The ambient humidity data and the ambient temperature data detected by the humidity sensor 331 and the temperature sensor 332 are converted into digital signals by the analog-to-digital converter 333; after the digital signals are transmitted to the internal processor 334, the internal processor 334 converts the digital signals into protocol signals complying with the I2C transmission protocol, and the protocol signals are transmitted to the MCU 310 through the I2C line.

In some embodiments, the sensor assembly 330 further includes an internal memory 336. An input end of the internal memory 336 is connected to the output end of the internal processor 334, and is configured to store the ambient humidity and the ambient temperature processed by the internal memory 334 and relevant data information required for detecting the ambient humidity and the ambient temperature, so as to facilitate subsequent checks.

Herein, the processor included in the sensor assembly 330 is referred to as an internal processor, and the memory included in the sensor assembly 330 is referred to as an internal memory. In some embodiments, the internal processor 334 includes a microprocessor, an application specific integrated circuit (ASIC), etc. In some embodiments, the internal memory includes a smart card, or a flash memory device (e.g., erasable programmable read-only memory (EPROM), a card, a stick, or a keyboard driver), etc.

FIG. 7 is a diagram showing an electrical connection between the sensor assembly 330 and the MCU 310, in accordance with some embodiments. As shown in FIG. 7, the sensor assembly 330 includes a first solder joint 51, a second solder joint S2, a third solder joint S3 and a fourth solder joint S4. The first solder joint 51 is electrically connected to the power management chip 320 through a wire bonding process; the second solder joint S2 is connected to a ground wire through a wire bonding process; the third solder joint S3 connects the SCL line to the I2C interface in the sensor assembly 330 through a wire bonding process, and the I2C interface in the sensor assembly 330 is connected to the communication signal interface of the MCU 310 through the SCL line; the fourth solder joint S4 connects the SDA line to the I2C interface in the sensor assembly 330 through a wire bonding process, and the I2C interface in the sensor assembly 330 is connected to the communication signal interface of the MCU 310 through the SDA line.

After the sensor assembly 330 is fixed on the circuit board 300, an end of the bonding wire is soldered to the first solder joint S1, and another end of the bonding wire is connected to the power management chip 320, so as to realize an electrical connection between the sensor assembly 330 and the power management chip 320; an end of another bonding wire is soldered to the second solder joint S2, and another end of the another bonding wire is connected to the ground wire, so as to realize an electrical connection between the sensor assembly 330 and the ground wire; an end of the SCL line is soldered to the third solder joint S3, and another end of the SCL line is connected to the communication signal interface of the MCU 310; an end of the SDA line is soldered to the fourth solder joint S4, and another end of the SDA line is connected to the communication signal interface of the MCU 310, so as to realize an electrical connection between the sensor assembly 330 and the MCU 310.

In order to facilitate the connection between the sensor assembly 330 and the MCU 310 through the I2C interface, the MCU 310 further includes an I2C interface, and the I2C interface of the sensor assembly 330 is connected to the I2C interface of the MCU 310 through the SCL line and the SDA line. The MCU 310 includes a fifth solder joint S5 and a sixth solder joint S6. The fifth solder joint S5 connects the SCL line to the I2C interface of the MCU 310 through a wire bonding process, and the sixth solder joint S6 connects the SDA line to the I2C interface of the MCU 310 through a wire bonding process. When the I2C interface of the sensor assembly 330 is connected to I2C interface of the MCU 310, an end of the SCL line is soldered to the third solder joint S3 of the sensor assembly 330, and another end of the SCL line is soldered to the fifth solder joint S5 of the MCU 310; an end of the SDA line is soldered to the fourth solder joint S4 of the sensor assembly 330, and another end of the SDA line is soldered to the sixth solder joint S6 of the MCU 310, so as to realize the connection between the I2C interface of the sensor assembly 330 and the I2C interface of the MCU 310.

The MCU 310 further includes a seventh solder joint S7 and an eighth solder joint S8. The seventh solder joint S7 is electrically connected to the power management chip 320 through a wire bonding process, and the eighth solder joint S8 is connected to the ground wire through a wire bonding process.

In some embodiments, the I2C interface of the sensor assembly 330 adopts an open drain mechanism. The SCL line and the SDA line can only output a signal of low level, but cannot actively output a signal of high level. Therefore, a low level output from the I2C interface of the sensor assembly 330 can only be pulled up to a high level by a pull-up resistor, so as to match the logic level of the MCU 310. In a case where the I2C interface of the sensor assembly 330 is connected to the I2C interface of the MCU 310 through the SCL line and the SDA line, the optical module 200 further includes a first pull-up resistor R1 and a second pull-up resistor R2 that are disposed on the I2C bus. The first pull-up resistor R1 is connected to the SCL line, the second pull-up resistor R2 is connected to the SDA line, and the first pull-up resistor R1 and the second pull-up resistor R2 are arranged in parallel. An end of the first pull-up resistor R1 is connected to the power management chip 320, and another end thereof is connected to the SCL line. An end of the second pull-up resistor R2 is connected to the power management chip 320, and another end thereof is connected to the SDA line.

In some embodiments, the sensor assembly 330 is disposed at a position, away from the light-emitting device 400, of the circuit board 300, and is electrically connected to the MCU 310, the power management chip 320 and the ground wire. The sensor assembly 330 is configured to detect the ambient humidity and the ambient temperature inside the optical module 200 in real time, and transmit the ambient humidity and the ambient temperature to the MCU 310 through the I2C interface. The MCU 310 controls and adjusts the cooling or heating temperature of the TEC 401 in the light-emitting device 400 according to the ambient humidity and ambient temperature, so as to avoid condensation on the surfaces of key optical devices on the TEC 401.

When the optical module operates in an environment of a relatively low humidity, for example, in an air-conditioned data center, the moisture content in the air is low (e.g., the relative humidity is less than or equal to 30%), then in a wide temperature range, such as 25° C. to 35° C., condensation will not occur on the heat exchange surface of the TEC. However, when the optical module operates in some extreme conditions, for example, when the optical module is tested in high temperature and high humidity conditions (e.g., the ambient temperature is greater than 35° C., such as 40° C., 50° C., 60° C., 70° C. or 80° C.; and the relative humidity of the air is greater than or equal to 85%, such as 85%, 90%, 95% or 100%), moisture will enter the non-hermetically sealed cover of the light-emitting device 400. After a period of time, the relative humidity inside the non-hermetically sealed cover of the light-emitting device 400 will increase significantly and even approach the relative humidity outside the non-hermetically sealed cover of the light-emitting device 400. If the temperature of the heat exchange surface of the TEC is low, for example, is less than or equal to 50° C., then condensation will occur on both the surface of the TEC and the optical devices installed on the surface, which will block the optical path and affect the normal operation of the optical module.

In a case where the effect of the ambient humidity on the temperature of the heat exchange surface of the TEC is not considered when the MCU 310 generates the control signal, the MCU 310 may generate the control signal only according to the ambient temperature in which the laser chip and other optical devices, disposed on the heat exchange surface of the TEC, operate, so as to cool or heat the laser chip and other optical devices.

However, if only the ambient temperature in which the laser chip and other optical devices operate is considered, the temperature on the heat exchange surface of the TEC may be lower than the dew point temperature inside the cover of the light-emitting device 400, which may easily cause condensation on the laser chip and other optical devices. In a case where the effect of the ambient humidity on the temperature of the heat exchange surface of the TEC is considered when the MCU 310 generates the control signal, the MCU 310 may generate the control signal according to both the ambient temperature and the ambient humidity in which the laser chip and other optical devices, disposed on the heat exchange surface of the TEC, operate. As a result, the temperature on the heat exchange surface of the TEC is higher than the dew point temperature corresponding to the ambient temperature and the ambient humidity in which the laser chip and other optical devices, disposed on the heat exchange surface of the TEC, operate, thereby avoiding condensation on the laser chip and other optical devices.

In some embodiments, the sensor assembly 330 is configured to obtain the ambient data inside the optical module and send the obtained ambient data to the MCU 310, the ambient data including the ambient temperature and the ambient humidity.

In the non-hermetic sealing method of the light-emitting device 400, the environment inside the light-emitting device 400 is communicated with the environment inside the optical module. Therefore, the environment inside the optical module may be considered to be equivalent to the environment inside the light-emitting device 400 when obtaining the ambient temperature data and the ambient humidity data. Therefore, the ambient data inside the optical module obtained by the sensor assembly 330 is the ambient data inside the light-emitting device 400.

Since the humidity and temperature changes in real time, the ambient humidity data and the ambient temperature data are also obtained in real time. For example, the ambient data may be obtained periodically at fixed intervals. For example, the sensor assembly 330 obtains the ambient data at intervals of 1 second.

The humidity sensor 331 in the sensor assembly 330 is configured to detect the ambient humidity and obtain the ambient humidity data, and send the obtained ambient humidity data to the analog-to-digital converter 333. The temperature sensor 332 in the sensor assembly 330 is configured to detect the ambient temperature and obtain the ambient temperature data, and send the obtained ambient temperature data to the analog-to-digital converter 333. The analog-to-digital converter 333 is configured to receive the ambient humidity data and the ambient temperature data, and convert the ambient humidity data and ambient temperature data into digital signals (i.e., ambient humidity and ambient temperature). The analog-to-digital converter 333 is further configured to send the digital signals to the internal processor 334. The internal processor 334 is configured to convert the digital signals into protocol signals complying with the I2C transmission protocol, and transmit the protocol signals to the MCU 310 through the I2C line.

In some embodiments, the sensor assembly 330 is configured to obtain the ambient humidity data but not the ambient temperature data. The ambient temperature data is obtained by the MCU 310 itself.

The MCU 310 is further configured to determine the dew point temperature corresponding to the ambient data according to the received ambient data.

The MCU 310 is further configured to, after receiving the ambient data sent by the sensor assembly 330, calculate the dew point temperature corresponding to the ambient data according to the following formula:

$$\frac{1}{{T}_{d}} = \frac{1}{T} - \frac{L n ( R H )}{L / R v} . \qquad ( 1 )$$

In the above formula, T is the ambient temperature received by the MCU 310 and is measured on a Kelvin scale (K), and RH is the ambient humidity received by the MCU 310. For example, the ambient humidity is relative humidity. Ln is the natural logarithm. Td is the dew point temperature when the ambient temperature is T and the ambient humidity is RH, and is measured on the Kelvin scale (K), and L divided by RV is 5423K (L/RV=5423K).

The MCU 310 is further configured to calculate the dew point temperature corresponding to the ambient humidity and the ambient temperature through other formulas according to the received ambient humidity and ambient temperature, which is not limited in the present disclosure. Any formula for calculating the dew point temperature by using the ambient temperature and ambient humidity inside the optical module falls within the protection scope of the present disclosure.

In some embodiments, the MCU 310 is further configured to obtain the dew point temperature corresponding to the received ambient humidity and ambient temperature in a manner of looking up the dew point temperature in a table. In this manner, the MCU 310 is configured to look up the corresponding dew point temperature in a table by using the ambient humidity and the ambient temperature inside the optical module collected in real time as an index.

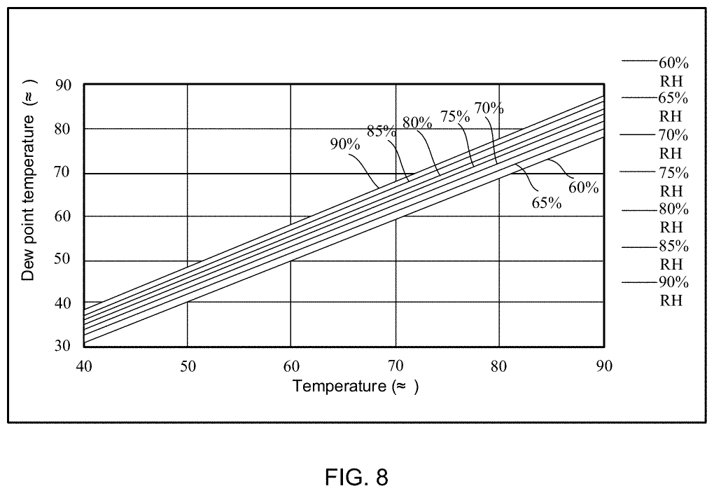

For example, FIG. 8 is a diagram showing a relationship between ambient humidity and dew-point temperature of an optical module under different ambient temperatures, in accordance with some embodiments. For example, in a case where the ambient temperature and the ambient humidity obtained by the MCU 310 are 70° C. and 85%, respectively, the corresponding dew point temperature is 67° C.; in a case where the ambient humidity and the ambient humidity obtained by the MCU 310 are 70° C. and 70%, respectively, the corresponding dew point temperature is 63° C. Under the same ambient temperature, the higher the ambient humidity, the higher the corresponding dew point temperature.

The MCU 310 is further configured to compare a difference between the received ambient temperature and the calculated dew point temperature with a buffer temperature, and determine whether the difference between the received ambient temperature and the calculated dew point temperature is greater than the buffer temperature.

If the difference (T-Td) between the received ambient temperature T and the calculated dew point temperature Td is less than or equal to the buffer temperature Tb, condensation is easy to occur on the surfaces of the optical devices on the heat exchange surface of the TEC. In this case, the MCU 310 is configured to control the TEC to adjust the temperature of the heat exchange surface thereof.

If the difference (T-Td) between the received ambient temperature T and the calculated dew point temperature Td is greater than the buffer temperature Tb, condensation is not easy to occur on the surfaces of the optical devices on the heat exchange surface of the TEC. In this case, the MCU 310 is configured to continue to compare the difference between the received ambient temperature and the calculated dew point temperature with the buffer temperature.

For example, the buffer temperature Tb is greater than or equal to 0° C. and less than or equal to 8° C. For example, the buffer temperature is 8° C., 7° C., 6° C., 5° C., 4° C., 3° C., 2° C., 1° C. or 0° C.

When the received ambient temperature T and the calculated dew point temperature Td are both measured on a Kelvin scale (K), and the buffer temperature Tb is measured on a Celsius scale (° C.), the buffer temperature Tb can be converted into a Kelvin temperature according to the relationship between the Kelvin scale and the Celsius scale.

In a case where the buffer temperature Tb is 0° C., it will not be determined whether the difference (T-Td) between the received ambient temperature T and the calculated dew point temperature Td is greater than the buffer temperature Tb; instead, it will be determined whether the ambient temperature T is greater than the calculated dew point temperature Td. In this case, if the ambient temperature T is equal to the dew point temperature Td, the MCU 310 will not control the TEC to adjust the temperature of the heat exchange surface thereof. This will increase the possibility of condensation on the optical devices on the heat exchange surface of the TEC. However, the present disclosure does not intend to abandon the technical solution that the buffer temperature Tb is 0° C.

In a case where the buffer temperature Tb is greater than 0° C., if the ambient temperature T is greater than the dew point temperature Td, the MCU 310 will control the TEC to adjust the temperature of the heat exchange surface thereof. Thus, it may be possible to avoid a situation in which the MCU 310 only controls the TEC to adjust the temperature of the heat exchange surface thereof when the ambient temperature T is equal to the dew point temperature Td, and thus avoid increasing the possibility of condensation on the optical devices on the heat exchange surface of the TEC.

It will be noted that, when it is determined whether condensation is easy to occur on the surfaces of the optical devices on the heat exchange surface of the TEC, the current temperature of the heat exchange surface of the TEC may be used to replace the ambient temperature received by the MCU 310. Therefore, in some embodiments, the MCU 310 is further configured to compare a difference between the current temperature of the heat exchange surface of the TEC and the calculated dew point temperature with the buffer temperature, and determine whether the difference between the current temperature of the heat exchange surface of the TEC and the calculated dew point temperature is greater than the buffer temperature.

It will be noted that, the current temperature of the heat exchange surface of the TEC is a target temperature of the heat exchange surface of the TEC indicated by the control signal sent by the MCU 310 to the driving chip 340 of the TEC.

If the difference between the current temperature of the heat exchange surface of the TEC and the calculated dew point temperature is less than or equal to the buffer temperature, condensation is easy to occur on the surfaces of the optical devices on the heat exchange surface of the TEC. In this case, the MCU 310 is configured to control the TEC to adjust the temperature of the heat exchange surface thereof.

If the difference between the current temperature of the heat exchange surface of the TEC and the calculated dew point temperature is greater than the buffer temperature, condensation is not easy to occur on the surfaces of the optical devices on the heat exchange surface of the TEC. In this case, the MCU 310 is configured to continue to compare the difference between the current temperature of the heat exchange surface of the TEC and the calculated dew point temperature with the buffer temperature.

It will be noted that, when the MCU 310 compares the difference between the current temperature of the heat exchange surface of the TEC and the calculated dew point temperature with the buffer temperature for the first time, since it is impossible to obtain the target temperature of the heat exchange surface of the TEC indicated by the control signal sent by the MCU 310 to the driving chip 340 of the TEC, the ambient temperature detected by the temperature sensor 332 may be used as the current temperature of the heat exchange surface of the TEC.

After determining that the difference between the received ambient temperature (or the current temperature of the heat exchange surface of the TEC) and the calculated dew point temperature is less than or equal to the buffer temperature, the MCU 310 is further configured to generate a control signal, and send the generated control signal to the driving chip 340 of the TEC, the control signal indicating the target temperature of the heat exchange surface of the TEC.

In some embodiments, the MCU 310 is further configured to determine a compensation temperature according to the received ambient temperature and the calculated dew point temperature. The target temperature of the heat exchange surface of the TEC indicated by the control signal is a sum of the calculated dew point temperature and the compensation temperature.

For example, the compensation temperature is in a range of 1° C. to 8° C. For example, the compensation temperature is 8° C., 7° C., 6° C., 5° C., 4° C., 3° C., 2° C. or 1° C.

When the received ambient temperature T and the calculated dew point temperature Td are both measured on a Kelvin scale (K), and the compensation temperature is measured on a Celsius scale (° C.), the compensation temperature can be converted into a Kelvin temperature according to the relationship between the Kelvin scale and the Celsius scale.

It will be noted that, by setting the compensation temperature to be in a range of 1° C. to 8° C., it may be possible to avoid a situation in which the MCU 310 needs to regenerate the control signal and control the driving chip 340 of the TEC to adjust the temperature of the heat exchange surface of the TEC (which increases the workload of the optical module) every time the ambient temperature inside the optical module changes slightly (e.g., the temperature increases or decreases by 1° C. to 3° C.) when the compensation temperature is too low (e.g., the compensation temperature is less than 1° C.); it may also be possible to avoid a situation in which the adjusted temperature of the heat exchange surface of the TEC becomes too high and affects the operating performance of the laser chip and other optical devices on the heat exchange surface of the TEC when the compensation temperature is too high (e.g., the compensation temperature is greater than 9° C.).

In some embodiments, the MCU 310 is further configured to receive a plurality of ambient temperatures (e.g., 2, 3 or 4 ambient temperatures), and arrange the plurality of ambient temperatures according to an order of acquisition time, so as to determine whether the current ambient temperature is in an upward trend or a downward trend. In a case where the arranged plurality of ambient temperatures are getting higher, the MCU 310 is configured to determine that the current ambient temperature is in an upward trend; in a case where the arranged plurality of ambient temperatures are getting lower, the MCU 310 is configured to determine that the current ambient temperature is in a downward trend.

When the MCU 310 determines that the current ambient temperature is in an upward trend, the MCU 310 is further configured to determine the compensation temperature to be a value in a range of 1° C. to 4° C.; when the MCU 310 determines that the current ambient temperature is in a downward trend, the MCU 310 is further configured to determine the compensation temperature to be a value in a range of 5° C. to 8° C.

In some embodiments, when the current temperature of the heat exchange surface of the TEC is used to replace the ambient temperature received by the MCU 310, the MCU 310 is further configured to determine the compensation temperature according to the current temperature of the heat exchange surface of the TEC and the calculated dew point temperature, and the target temperature of the heat exchange surface of the TEC indicated by the control signal is a sum of the calculated dew point temperature and the compensation temperature.

For example, the compensation temperature is in a range of 1° C. to 8° C. For example, the compensation temperature is 8° C., 7° C., 6° C., 5° C., 4° C., 3° C., 2° C. or 1° C.

The practice that the MCU 310 is configured to determine the compensation temperature according to the current temperature of the heat exchange surface of the TEC and the calculated dew point temperature is similar to the practice that the MCU 310 is configured to determine the compensation temperature according to the received ambient temperature and the calculated dew point temperature, and details will not be repeated here.

The driving chip 340 of the TEC is configured to adjust the temperature of the heat exchange surface of the TEC to the target temperature of the heat exchange surface of the TEC according to the received control signal.

The target temperature of the heat exchange surface of the TEC is the sum of the calculated dew point temperature and the compensation temperature. As such, there is an appropriate difference between the current temperature of the heat exchange surface of the TEC and the dew point temperature, which avoids condensation on the optical devices on the heat exchange surface of the TEC.

The optical module provided by some embodiments of the present disclosure may be able to keep the temperature of the heat exchange surface of the TEC above the dew point temperature, and avoid condensation on the optical devices on the heat exchange surface of the TEC and the surface thereof. In this way, it may be possible to guarantee the performance of the optical module, improve the reliability and stability of the optical module, and ensure that the optical module can operate normally in extreme conditions.

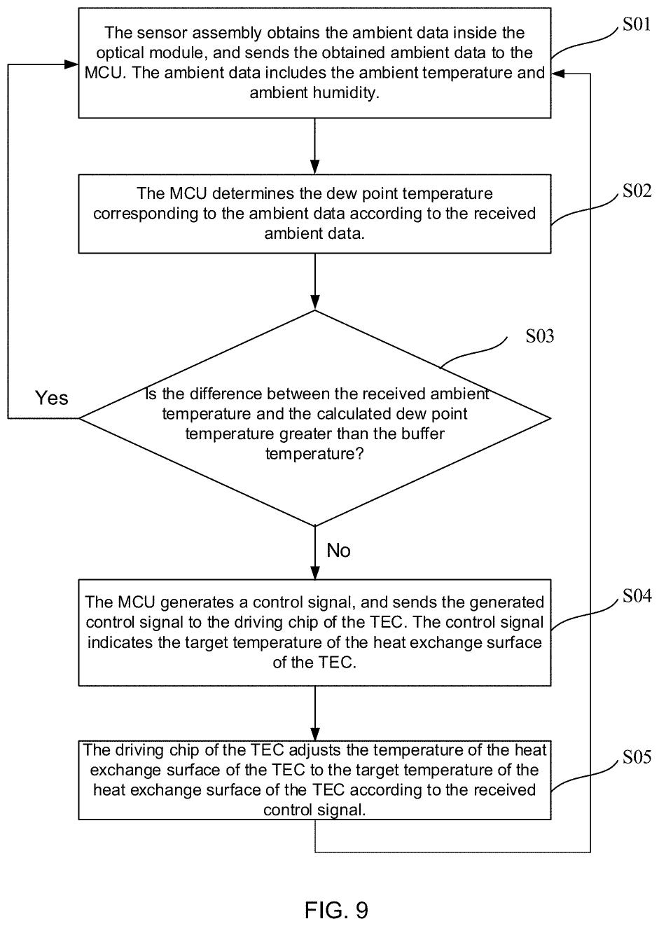

FIG. 9 is a flow diagram of a temperature control method of an optical module, in accordance with some embodiments. Some embodiments of the present disclosure further provide a temperature control method of an optical module, and the optical module may be the optical module as described above. As shown in FIG. 9, the temperature control method of the optical module includes steps 01 to 05 (S01 to S05).

In S01, the sensor assembly 330 obtains the ambient data inside the optical module, and sends the obtained ambient data to the MCU 310. The ambient data includes the ambient temperature and ambient humidity.

In the non-hermetic sealing method of the light-emitting device 400, the environment inside the light-emitting device 400 is communicated with the environment inside the optical module. Therefore, the environment inside the optical module may be considered to be equivalent to the environment inside the light-emitting device 400 when obtaining the ambient temperature and ambient humidity. Therefore, the ambient data inside the optical module obtained by the sensor assembly 330 is the ambient data inside the light-emitting device 400.

Since the humidity and temperature changes in real time, the ambient humidity data and the ambient temperature data are also obtained in real time. For example, the ambient data may be obtained periodically at fixed intervals. For example, the sensor assembly 330 obtains the ambient data at intervals of 1 second.

The humidity sensor 331 detects the ambient humidity and obtains the ambient humidity data, and sends the obtained ambient humidity data to the analog-to-digital converter 333. The temperature sensor 332 detects the ambient temperature and obtains the ambient temperature data, and sends the obtained ambient temperature data to the analog-to-digital converter 333. The analog-to-digital converter 333 receives the ambient humidity data and ambient temperature data, and converts the ambient humidity data and ambient temperature data into the ambient humidity and ambient temperature. Next, the analog-to-digital converter 333 sends the ambient humidity and ambient temperature to the internal processor 334, and the internal processor 334 converts the ambient humidity and ambient temperature into protocol signals complying with the I2C transmission protocol, and transmits the protocol signals to the MCU 310 through the I2C line.

In some embodiments, the sensor assembly 330 only obtains the ambient humidity data inside the optical module, but not the ambient temperature data. The ambient temperature data is obtained by the MCU 310 itself.

In S02, the MCU 310 determines the dew point temperature corresponding to the ambient data according to the received ambient data.

The MCU 310 receives the ambient humidity and ambient temperature, and calculates the dew point temperature corresponding to the ambient humidity and ambient temperature according to the following formula:

$$\frac{1}{{T}_{d}} = \frac{1}{T} - \frac{L n ( R H )}{L / R v} . \qquad ( 1 )$$

In the above formula, T is the ambient temperature received by the MCU 310 and is measured on a Kelvin scale (K), and RH is the ambient humidity received by the MCU 310. For example, the ambient humidity is relative humidity. Ln is the natural logarithm. Td is the dew point temperature when the ambient temperature is T and the ambient humidity is RH, and is measured on the Kelvin scale (K), and L divided by RV is 5423K (L/RV=5423K).

According to the ambient humidity and ambient temperature received by the MCU 310, there may be various formulas according to which the dew point temperature corresponding to the ambient humidity and ambient temperature is calculated, which is not limited in the present disclosure. Any formula for calculating the dew point temperature by using the ambient temperature and ambient humidity inside the optical module falls within the protection scope of the present disclosure.

In some embodiments, the MCU 310 may also adopt a manner of looking up the dew point temperature in a table. In this manner, the MCU 310 looks up the dew point temperature corresponding to the received ambient humidity and ambient temperature in a table by using the received ambient humidity and ambient temperature as an index.

In S03, the MCU 310 compares the difference between the received ambient temperature and the calculated dew point temperature with the buffer temperature, and determines whether the difference between the received ambient temperature and the calculated dew point temperature is greater than the buffer temperature.

If the difference (T−Td) between the received ambient temperature T and the calculated dew point temperature Td is less than or equal to the buffer temperature Tb, condensation is easy to occur on the surfaces of the optical devices on the heat exchange surface, and S04 is performed.

If the difference (T−Td) between the received ambient temperature T and the calculated dew point temperature Td is greater than the buffer temperature Tb, condensation is not easy to occur on the surfaces of the optical devices on the heat exchange surface of the TEC, and the process returns to S01.

For example, the buffer temperature Tb is greater than or equal to 0° C. and less than or equal to 8° C. For example, the buffer temperature is 8° C., 7° C., 6° C., 5° C., 4° C., 3° C., 2° C., 1° C. or 0° C.

In a case where the buffer temperature Tb is 0° C., it will not be determined whether the difference between the received ambient temperature T and the calculated dew point temperature Td is greater than the buffer temperature Tb; instead, it will be determined whether the ambient temperature T is greater than the calculated dew point temperature Td. In this case, if the ambient temperature T is equal to the dew point temperature Td, the MCU 310 will not control the TEC to adjust the temperature of the heat exchange surface of the TEC. This will increase the possibility of condensation on the optical devices on the heat exchange surface of the TEC. However, the present disclosure does not intend to abandon the technical solution that the buffer temperature Tb is 0° C.

In a case where the buffer temperature Tb is greater than 0° C., if the ambient temperature T is greater than the dew point temperature Td, the MCU 310 will control the TEC to adjust the temperature of the heat exchange surface thereof. Thus, it may be possible to avoid a situation in which the MCU 310 only controls the TEC to adjust the temperature of the heat exchange surface thereof when the ambient temperature T is equal to the dew point temperature Td, and thus avoid increasing the possibility of condensation on the optical devices on the heat exchange surface of the TEC.

In S04, the MCU 310 generates a control signal, and sends the generated control signal to the driving chip 340 of the TEC. The control signal indicates the target temperature of the heat exchange surface of the TEC.

After determining that the difference between the received ambient temperature and the calculated dew point temperature is less than or equal to the buffer temperature, the MCU 310 generates the compensation temperature according to the received ambient temperature and the calculated dew point temperature. The target temperature of the heat exchange surface of the TEC indicated by the control signal is a sum of the calculated dew point temperature and the compensation temperature.

For example, the compensation temperature is 1° C. to 8° C. For example, the compensation temperature is 8° C., 7° C., 6° C., 5° C., 4° C., 3° C., 2° C. or 1° C.

It will be noted that, by setting the compensation temperature to be in a range of 1° C. to 8° C., it may be possible to avoid a situation in which the MCU 310 needs to regenerate the control signal and control the driving chip 340 of the TEC to adjust the temperature of the heat exchange surface of the TEC (which increases the workload of the optical module) every time the ambient temperature inside the optical module changes slightly (e.g., the temperature increases or decreases by 1° C. to 3° C.) when the compensation temperature is too low (e.g., the compensation temperature is less than 1° C.); it may also be possible to avoid a situation in which the adjusted temperature of the heat exchange surface of the TEC becomes too high and affects the operating performance of the laser chip and other optical devices on the heat exchange surface of the TEC when the compensation temperature is too high (e.g., the compensation temperature is greater than 9° C.).

In some embodiments, the MCU 310 receives a plurality of ambient temperatures (e.g., 2, 3 or 4 ambient temperatures), and arrange the plurality of ambient temperatures according to the order of acquisition time, so as to determine whether the current ambient temperature is in an upward trend or a downward trend. In a case where the arranged ambient temperatures are getting higher, the MCU 310 determines that the current ambient temperature is in an upward trend; in a case where the arranged ambient temperatures are getting lower, the MCU 310 determines that the current ambient temperature is in a downward trend.

When it is determined that the current ambient temperature is in an upward trend, the MCU 310 determines the compensation temperature to be a value in the range of 1° C. to 4° C.; when it is determined that the current ambient temperature is in a downward trend, the MCU 310 determines the compensation temperature to be a value in the range of 5° C. to 8° C.

In S05, the driving chip 340 of the TEC adjusts the temperature of the heat exchange surface of the TEC to the target temperature of the heat exchange surface of the TEC according to the received control signal.

The target temperature of the heat exchange surface of the TEC is the sum of the calculated dew point temperature and the compensation temperature. As such, there is an appropriate difference between the current temperature of the heat exchange surface of the TEC and the dew point temperature, which avoids condensation on the optical devices on the heat exchange surface of the TEC.

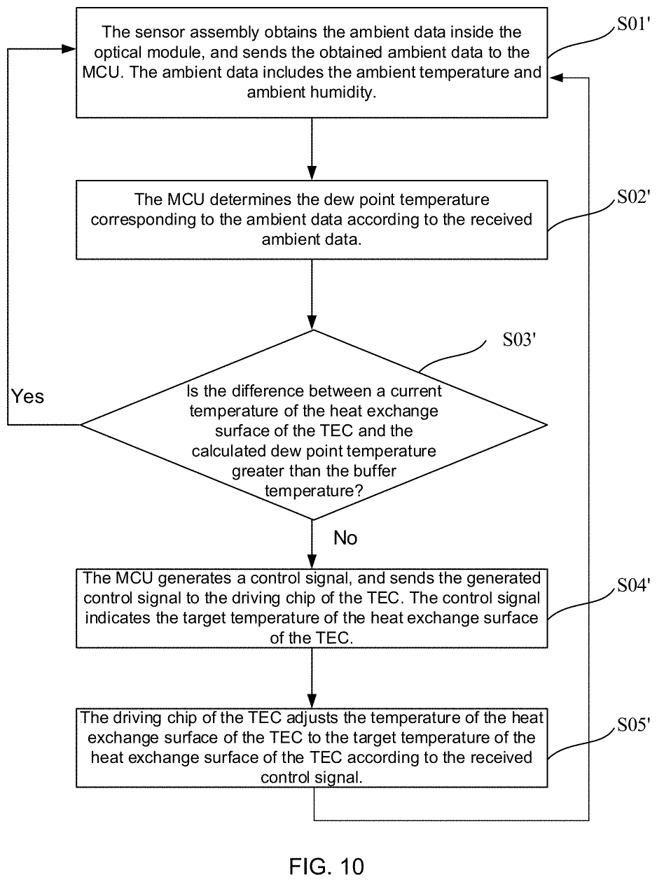

FIG. 10 is a flow diagram of another temperature control method of an optical module, in accordance with some embodiments. Some embodiments of the present disclosure further provide another temperature control method of an optical module, and the optical module may be the optical module as described above. As shown in FIG. 10, the temperature control method of the optical module includes steps S01′ to S05′.

In S01′, the sensor assembly 330 obtains the ambient data inside the optical module, and sends the obtained ambient data to the MCU 310. The ambient data includes the ambient temperature and ambient humidity.

In S02′, the MCU 310 determines the dew point temperature corresponding to the ambient data according to the received ambient data.

In S03′, the MCU 310 compares the difference between the current temperature of the heat exchange surface of the TEC and the calculated dew point temperature with the buffer temperature, and determines whether the difference between the current temperature of the heat exchange surface of the TEC and the calculated dew point temperature is greater than the buffer temperature.

It will be noted that, the current temperature of the heat exchange surface of the TEC is the target temperature of the heat exchange surface of the TEC indicated by the control signal sent by the MCU 310 to the driving chip 340 of the TEC.

If the difference between the current temperature of the heat exchange surface of the TEC and the calculated dew point temperature is less than or equal to the buffer temperature, condensation is easy to occur on the surfaces of the optical devices on the heat exchange surface of the TEC, and S04′ is performed. If the difference between the current temperature of the heat exchange surface of the TEC and the calculated dew point temperature is greater than the buffer temperature, condensation is not easy to occur on the surfaces of the optical devices on the heat exchange surface of the TEC, and the process returns to S01′.

It will be noted that, when the MCU 310 compares the difference between the current temperature of the heat exchange surface of the TEC and the calculated dew point temperature with the buffer temperature for the first time, since it is impossible to obtain the target temperature of the heat exchange surface of the TEC indicated by the control signal sent by the MCU 310 to the driving chip 340 of the TEC, the ambient temperature detected by the temperature sensor 332 may be used as the current temperature of the heat exchange surface of the TEC.

In S04′, the MCU 310 generates a control signal, and sends the generated control signal to the driving chip 340 of the TEC. The control signal indicates the target temperature of the heat exchange surface of the TEC.

After determining that the difference between the current temperature of the heat exchange surface of the TEC and the calculated dew point temperature is less than or equal to the buffer temperature, the MCU 310 determines the compensation temperature according to the current temperature of the heat exchange surface of the TEC and the calculated dew point temperature. The target temperature of the heat exchange surface of the TEC indicated by the control signal is the sum of the calculated dew point temperature and the compensation temperature.

For example, the compensation temperature is in a range of 1° C. to 8° C. For example, the compensation temperature is 8° C., 7° C., 6° C., 5° C., 4° C., 3° C., 2° C. or 1° C.

The practice that the MCU 310 determines the compensation temperature according to the current temperature of the heat exchange surface of the TEC and the calculated dew point temperature is similar to the practice that the MCU 310 determines the compensation temperature according to the received ambient temperature and the calculated dew point temperature, and details will not be repeated here.

In S05′, the driving chip 340 of the TEC adjusts the temperature of the heat exchange surface of the TEC to the target temperature of the heat exchange surface of the TEC according to the received control signal.

The beneficial effects of the temperature control method of the optical module provided by some embodiments of the present disclosure are the same as the beneficial effects of the optical module as described above, and details will not be repeated here.

Some embodiments of the present disclosure provide a non-transitory computer-readable storage medium. The non-transitory computer-readable storage medium has stored thereon computer program instructions that, when run on a processor (e.g., the MCU 310), cause the processor to perform the temperature control method as described above.

For example, the non-transitory computer-readable storage medium may include, but is not limited to: a magnetic storage device (e.g., a hard disk, a floppy disk, or a magnetic tape), an optical disk (e.g., a compact disk (CD)), a digital versatile disk (DVD), a smart card and a flash memory device (e.g., an erasable programmable read-only memory (EPROM), a card, a stick or a key drive). The various computer-readable storage media described in the embodiments of the present disclosure may represent one or more devices and/or other machine-readable storage media for storing information. The term “machine-readable storage medium” may include, but is not limited to, wireless channels and various kinds of other media capable of storing, containing, and/or carrying instruction(s) and/or data.

The design concepts of the present disclosure are not limited to being applied to a high-speed optical communication module circuit, but can also be applied to other types of optical modules, as well as other products and fields that need to avoid condensation problems.

Finally, it will be noted that, the above embodiments are only used to illustrate the technical solutions of the present disclosure, but not to limit the same. Although the present disclosure are described in detail with reference to the foregoing embodiments, those of ordinary skill in the art will understand that the technical solutions described in the foregoing embodiments may still be modified, or some of the technical features may be equivalently replaced, and these modifications or replacements do not deviate essences of corresponding technical solutions from the spirit and scope of the technical solutions of the embodiments of the present disclosure.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

What is claimed is:

1. An optical module, comprising:
a shell;
a circuit board disposed in the shell;
a light-emitting device disposed in the shell, the light-emitting device including:
a non-hermetically sealed cover;
a laser chip disposed in the cover, the laser chip being configured to emit an optical signal; and
a thermo electric cooler disposed in the cover, the laser chip being disposed on the thermo electric cooler, and the thermo electric cooler being configured to adjust a temperature of the heat exchange surface of the thermo electric cooler connected to the laser chip;
a sensor assembly disposed on the circuit board, the sensor assembly being configured to detect ambient data inside the optical module, the ambient data including at least ambient humidity; and
a processor disposed on the circuit board, the processor being configured to receive the ambient data detected by and sent from the sensor assembly, and control the thermo electric cooler to adjust the temperature of the heat exchange surface of the thermo electric cooler to a target temperature according to the ambient data.

2. The optical module according to claim 1, wherein the sensor assembly includes a humidity sensor;
the humidity sensor is configured to detect the ambient humidity and obtain ambient humidity data, and send the obtained ambient humidity data to the processor.

3. The optical module according to claim 2, wherein the sensor assembly further includes a temperature sensor;
the temperature sensor is configured to detect ambient temperature and obtain ambient temperature data, and send the obtained ambient temperature data to the processor.

4. The optical module according to claim 3, wherein the sensor assembly further includes:
an analog-to-digital converter, the analog-to-digital converter being configured to receive the ambient humidity data and the ambient temperature data, and convert the ambient humidity data and the ambient temperature data from an analog signal mode to a digital signal mode; and
an internal processor, the internal processor being configured to convert obtained digital signals into protocol signals complying with a transmission protocol, and transmit the protocol signals to the processor.

5. The optical module according to claim 4, wherein the sensor assembly further includes a third solder joint and a fourth solder joint, and the processor includes a fifth solder joint and a sixth solder joint;
the third solder joint is electrically connected to both the internal processor and the fifth solder joint; and
the fourth solder joint is electrically connected to both the internal processor and the sixth solder joint.

6. The optical module according to claim 5, wherein the sensor assembly further includes a first solder joint and a second solder joint, and the processor further includes a seventh solder joint and an eighth solder joint;
the first solder joint and the seventh solder joint are electrically connected to a power supply, and the second solder joint and the eighth solder joint are grounded.

7. The optical module according to claim 6, wherein the sensor assembly further includes:
a first pull-up resistor, an end of the first pull-up resistor being electrically connected to the power supply, and another end of the first pull-up resistor being electrically connected to the third solder joint and the fifth solder joint; and
a second pull-up resistor, an end of the second pull-up resistor being electrically connected to the power supply, and another end of the second pull-up resistor being electrically connected to the fourth solder joint and the sixth solder joint.

8. The optical module according to claim 1, wherein
the processor is further configured to determine a dew point temperature inside the cover corresponding to the ambient data according to the received ambient data;
the processor is further configured to determine whether a difference between the received ambient temperature and a calculated dew point temperature is greater than a buffer temperature, or, the processor is further configured to determine whether a difference between a current temperature of the heat exchange surface of the thermo electric cooler and the calculated dew point temperature is greater than the buffer temperature;
in a case where the difference between the received ambient temperature and the calculated dew point temperature is less than or equal to the buffer temperature, or, in a case where the difference between the current temperature of the heat exchange surface of the thermo electric cooler and the calculated dew point temperature is less than or equal to the buffer temperature, the processor is configured to control the thermo electric cooler to adjust the temperature of the heat exchange surface of the thermo electric cooler to the target temperature.

9. The optical module according to claim 8, wherein
the processor is further configured to, after receiving the ambient data, calculate the dew point temperature corresponding to the ambient data according to a following formula:
$$\frac{1}{{T}_{d}} = \frac{1}{T} - \frac{L n ( R H )}{L / R v} ,$$
wherein
T is the ambient temperature received by the processor and is measured on a Kelvin scale (K), RH is the ambient humidity received by the processor, Ln is a natural logarithm, T_{d} is the dew point temperature when the ambient temperature is T and the ambient humidity is RH, and is measured on the Kelvin scale (K), and L divided by RV is 5423K (L/RV=5423K).

10. The optical module according to claim 8, wherein
the buffer temperature is greater than or equal to 0° C. and is less than or equal to 8° C.

11. The optical module according to claim 8, further comprising a driving chip of the thermo electric cooler, the driving chip of the thermo electric cooler being disposed on the circuit board, wherein
the processor is further configured to generate a control signal, and send the generated control signal to the driving chip of the thermo electric cooler, the control signal indicating the target temperature; and
the driving chip of the thermo electric cooler is configured to adjust the temperature of the heat exchange surface of the thermo electric cooler to the target temperature according to the received control signal.

12. The optical module according to claim 11, wherein
the processor is further configured to determine a compensation temperature according to the received ambient temperature and the calculated dew point temperature, and the target temperature is a sum of the calculated dew point temperature and the compensation temperature.

13. The optical module according to claim 12, wherein
the processor is further configured to receive a plurality of ambient temperatures, and arrange the plurality of ambient temperatures according to an order of acquisition time, so as to determine whether a current ambient temperature is in an upward trend or a downward trend;
in a case where the arranged plurality of ambient temperatures are getting higher, the processor is configured to determine that the current ambient temperature is in the upward trend, and the compensation temperature is determined to be a value in a range of 1° C. to 4° C.;
in a case where the arranged plurality of ambient temperatures are getting lower, the processor is configured to determine that the current ambient temperature is in the downward trend, and the compensation temperature is determined to be a value in a range of 5° C. to 8° C.

14. A temperature control method of an optical module, comprising:
obtaining, by a sensor assembly, ambient data inside the optical module;
sending, by the sensor assembly, the obtained ambient data to a processor, the ambient data including at least ambient humidity;
receiving, by the processor, the ambient data obtained by the sensor assembly; and
controlling, by the processor, the thermo electric cooler to adjust a temperature of a heat exchange surface of a thermo electric cooler to a target temperature according to the ambient data.

15. The temperature control method of the optical module according to claim 14, wherein
controlling, by the processor, the thermo electric cooler to adjust the temperature of the heat exchange surface of the thermo electric cooler to the target temperature according to the ambient data, includes:
determining, by the processor, a dew point temperature inside a cover of the optical module corresponding to the ambient data according to the received ambient data;
determining, by the processor, whether a difference between the received ambient temperature and a calculated dew point temperature is greater than a buffer temperature, or, determining, by the processor, whether a difference between a current temperature of the heat exchange surface of the thermo electric cooler and the calculated dew point temperature is greater than the buffer temperature; and
in a case where the difference between the received ambient temperature and the calculated dew point temperature is less than or equal to the buffer temperature, or, in a case where the difference between the current temperature of the heat exchange surface of the thermo electric cooler and the calculated dew point temperature is less than or equal to the buffer temperature, controlling, by the processor, the thermo electric cooler to adjust the temperature of the heat exchange surface of the thermo electric cooler to the target temperature.

16. The temperature control method of the optical module according to claim 15, wherein
determining, by the processor, the dew point temperature corresponding to the ambient data according to the received ambient data, includes:
calculating, by the processor, the dew point temperature according to a following formula:
$$\frac{1}{{T}_{d}} = \frac{1}{T} - \frac{L n ( R H )}{L / R v} ,$$
wherein
T is the ambient temperature received by the processor and is measured on a Kelvin scale (K), RH is the ambient humidity received by the processor, Ln is a natural logarithm, T_{d} is the dew point temperature when the ambient temperature is T and the ambient humidity is RH, and is measured on the Kelvin scale (K), and L divided by RV is 5423K (L/RV=5423K).

17. The temperature control method of the optical module according to claim 15, wherein
controlling, by the processor, the thermo electric cooler to adjust the temperature of the heat exchange surface of the thermo electric cooler to the target temperature according to the ambient data, further includes:
generating, by the processor, a control signal;
sending, by the processor, the generated control signal to a driving chip of the thermo electric cooler, the control signal indicating the target temperature; and
adjusting, by the driving chip of the thermo electric cooler, the temperature of the heat exchange surface of the thermo electric cooler to the target temperature according to the received control signal.

18. The temperature control method of the optical module according to claim 17, wherein generating, by the processor, the control signal, includes:
determining, by the processor, a compensation temperature according to the received ambient temperature and the calculated dew point temperature; and
generating, by the processor, the control signal, the control signal indicating the target temperature, and the target temperature being a sum of the calculated dew point temperature and the compensation temperature.

19. The temperature control method of the optical module according to claim 18, wherein determining, by the processor, the compensation temperature according to the received ambient temperature and the calculated dew point temperature, includes:
receiving, by the processor, a plurality of ambient temperatures, and arranging, by the processor, the plurality of ambient temperatures according to an order of acquisition time, so as to determine whether a current ambient temperature is in an upward trend or a downward trend;
determining, by the processor, that the current ambient temperature is in the upward trend in a case where the arranged plurality of ambient temperatures are getting higher, and determining, by the processor, the compensation temperature to be a value in a range of 1° C. to 4° C.; and
determining, by the processor, that the current ambient temperature is in the downward trend in a case where the arranged plurality of ambient temperatures are getting lower, and determining, by the processor, the compensation temperature to be a value in a range of 5° C. to 8° C.

20. A non-transitory computer-readable storage medium having stored thereon computer program instructions that, when run on a processor, cause the processor to execute the temperature control method of the optical module according to claim 14.
